(19) United States
(12) Patent Application Publication
(10) Pub. No.: US 2019/0189850 A1
(43) Pub. Date: Jun. 20, 2019

(54) LIGHT-EMITTING DEVICE

(71) Applicant: EPISTAR CORPORATION, Hsinchu (TW)

(72) Inventors: Hsin-Ying WANG, Hsinchu (TW); Hui-Chun YEH, Hsinchu (TW); Li-Ming CHANG, Hsinchu (TW); Chien-Fu SHEN, Hsinchu (TW); Chen OU, Hsinchu (TW)

(21) Appl. No.: 16/220,444

(22) Filed: Dec. 14, 2018

Related U.S. Application Data
(60) Provisional application No. 62/607,689, filed on Dec. 19, 2017.

(51) Int. Cl. H01L 33/38; H01L 33/32; H01L 33/14; H01L 33/62; H01L 33/20; H01L 33/00

(52) U.S. Cl. CPC H01L 33/38; H01L 33/32; H01L 33/0075; H01L 33/62; H01L 33/20; H01L 33/145

(57) ABSTRACT

A light-emitting device, includes a first semiconductor stack formed on a substrate, including a first semiconductor layer, a second semiconductor layer and an active layer formed therebetween; a first electrode formed on the first semiconductor layer; a second electrode formed on the second semiconductor layer, including a second pad electrode and a second finger electrode extending from the second pad electrode; a second current blocking region formed under the second electrode, including a second core region under the second pad electrode and a extending region under the second finger electrode; and a transparent conductive layer, formed on the second semiconductor layer and covering the extending region; wherein a contour of the second core region has a shape different from that of the second pad electrode; wherein the transparent conductive layer includes a first opening having a width wider than a width of the second pad electrode, wherein the second finger electrode includes a portion extending from the contour of the second pad electrode and having a width wider than other portion of the second finger electrode, and part of the portion is not covered by the transparent conductive layer.

### CROSS-REFERENCE TO RELATED APPLICATIONS

This application claims priority to and the benefit of U.S. provisional application No. 62/607,689 filed on Dec. 19, 2017, and the content of which is incorporated by reference in its entirety.

### BACKGROUND

### Technical Field

The present disclosure relates to a light-emitting device, more particularly, to a light-emitting device with uniform current spreading and improved brightness.

### Description of the Related Art

The light-emitting diodes (LEDs) of the solid-state lighting elements have the characteristics of low power consumption, low heat generation, long operation life, crash proof, small volume, quick response and good opto-electrical property like light emission with a stable wavelength, so the LEDs have been widely used in household appliances, indicator light of instruments, and opto-electrical products, etc. As the opto-electrical technology develops, the solid-state lighting elements have great progress in the light efficiency, operation life and the brightness, and LEDs are expected to become the main stream of the lighting devices in the near future.

A conventional LED basically includes a substrate, an n-type semiconductor layer, an active layer and a p-type semiconductor layer formed on the substrate, and p, n-electrodes respectively formed on the p-type/n-type semiconductor layers. When imposing a certain level of forward voltage to the LED via the electrodes, holes from the p-type semiconductor layer and electrons from the n-type semiconductor layer are combined in the active layer to generate light. However, the electrodes shelter light emitted from the active layer, and current may be crowded in semiconductor layers near the electrodes. Thus, optimized electrode and current blocking structures are needed for improving brightness, optical field uniformity and lowering an operating voltage of the LED.

### SUMMARY OF THE DISCLOSURE

A light-emitting device, includes a substrate; a first semiconductor stack formed on the substrate, including a first semiconductor layer, a second semiconductor layer and an active layer formed therebetween; a first electrode formed on the first semiconductor layer; a second electrode formed on the second semiconductor layer, including a second pad electrode and a second finger electrode extending from the second pad electrode; a second current blocking region formed under the second electrode, including a second core region under the second pad electrode and a extending region under the second finger electrode; and a transparent conductive layer, formed on the second semiconductor layer and covering the extending region; wherein a contour of the second core region has a shape different from that of the second pad electrode; wherein the transparent conductive layer includes a first opening having a width wider than a width of the second pad electrode, wherein the second finger electrode includes a portion extending from the contour of the second pad electrode and having a width wider than other portion of the second finger electrode, and part of the portion is not covered by the transparent conductive layer.

A light-emitting device, includes a substrate; a first semiconductor stack formed on the substrate, including a first semiconductor layer, a second semiconductor layer and an active layer formed therebetween; an exposed region formed in the first semiconductor stack, including a side surface and a bottom including an upper surface of the first semiconductor layer; a first electrode formed in the exposed region and electrically connecting to the first semiconductor layer, including a first pad electrode and a first finger electrode extending from the first pad electrode; and a first current blocking region formed under the first electrode, including a plurality of islands under the first finger electrode; wherein a shortest distance between the side surface of the exposed region and one of the plurality of islands is not smaller than 1 μm.

A light-emitting device, includes a substrate; a first semiconductor stack formed on the substrate, including a first semiconductor layer, a second semiconductor layer and an active layer formed therebetween; an exposed region formed in the first semiconductor stack, including a bottom including an upper surface of the first semiconductor layer; a first electrode formed in the exposed region and electrically connecting to the first semiconductor layer, including a first pad electrode; and a first current blocking region formed under the first pad electrode; wherein the first pad electrode contacts an area of the upper surface of the first semiconductor layer outside of the first current blocking region; and wherein the first pad electrode includes a first side surface and the first current blocking region includes a second side surface, and wherein a slope of the first side surface is greater than a slope of the second side surface.

### BRIEF DESCRIPTION OF THE DRAWINGS

FIGS. 1-2D show a light-emitting device 1 in accordance with a first embodiment of the present application.

FIGS. 3A and 3B respectively show a cross-sectional view taken along line C-C′ of the light-emitting device 1 in FIG. 1, in accordance with different embodiments of the present application.

FIGS. 4A-4C show a light-emitting device 2 in accordance with a second embodiment of the present application.

FIGS. 5A and 5B respectively show a cross-sectional view taken along line C-C′ of the light-emitting device 2 in FIG. 4, in accordance with different embodiments of the present application.

FIGS. 6A-6F show a light-emitting device 3 in accordance with a third embodiment of the present application and the different embodiments of the light-emitting device 3.

FIG. 6G shows an enlarge view of partial areas of a light-emitting device in accordance with another embodiment of the present application.

FIGS. 7A-7D show a light-emitting device 4 in accordance with a fourth embodiment of the present application.

FIGS. 8A-8B respectively show a partial top view of the light-emitting device, in accordance with different embodiments of the present application.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

### First Embodiment

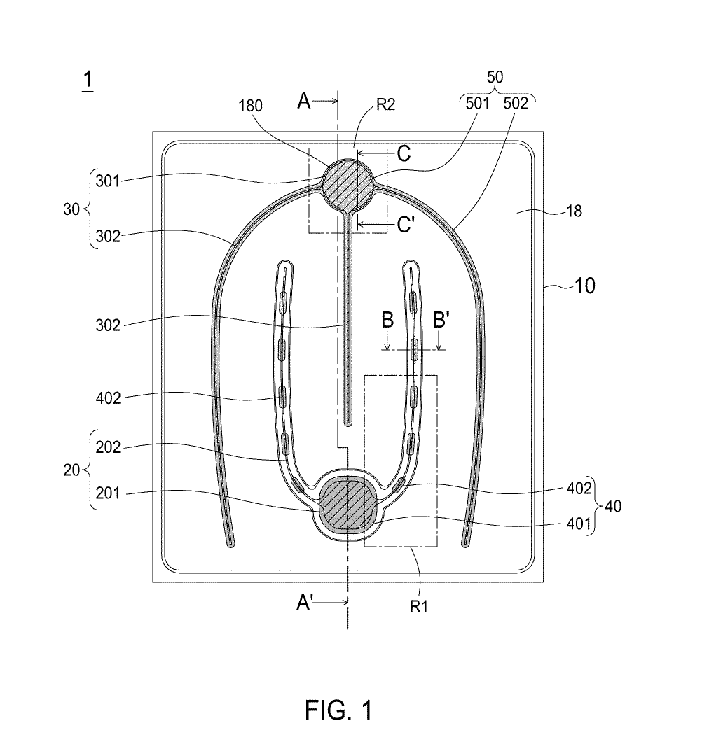

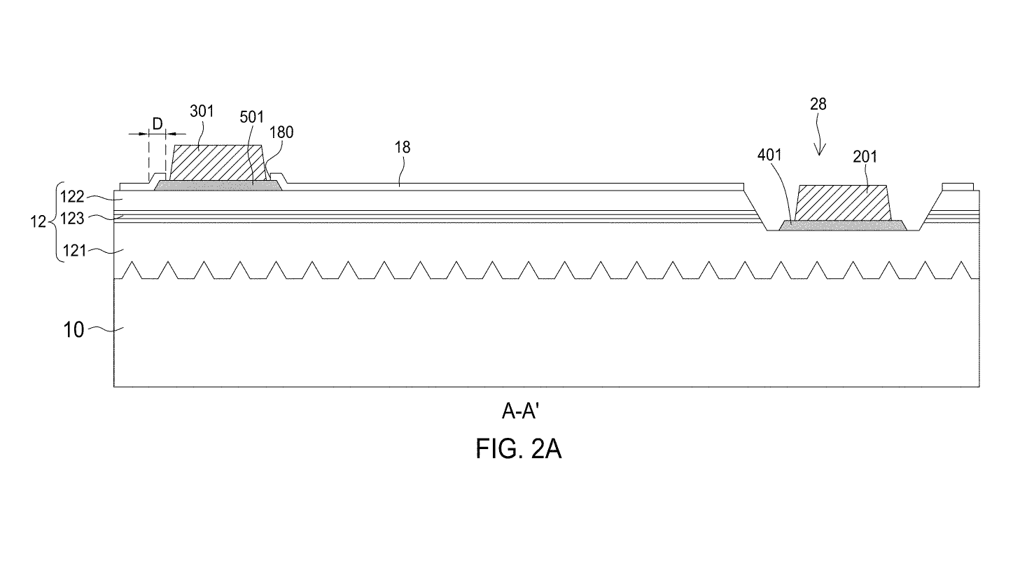

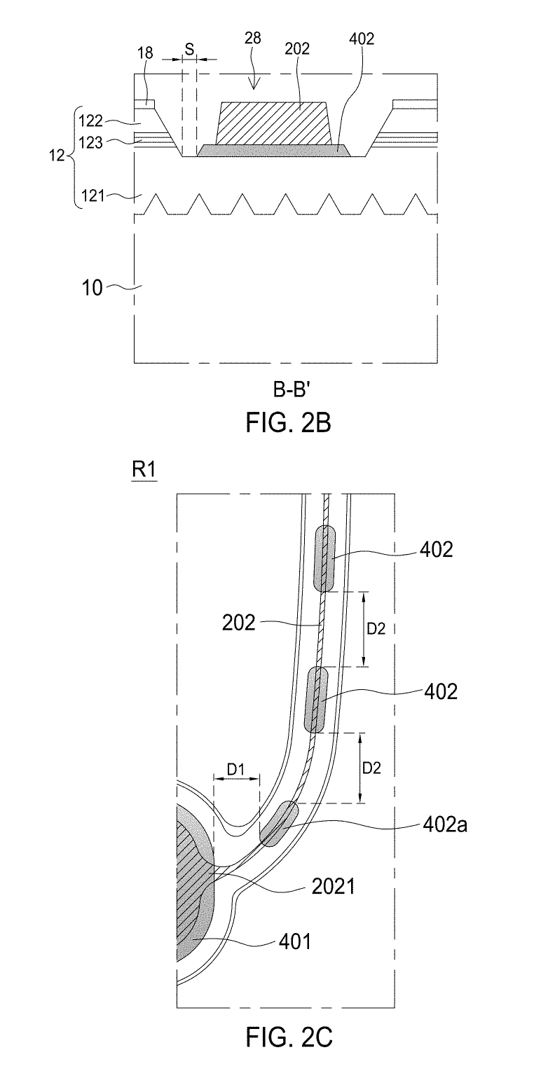

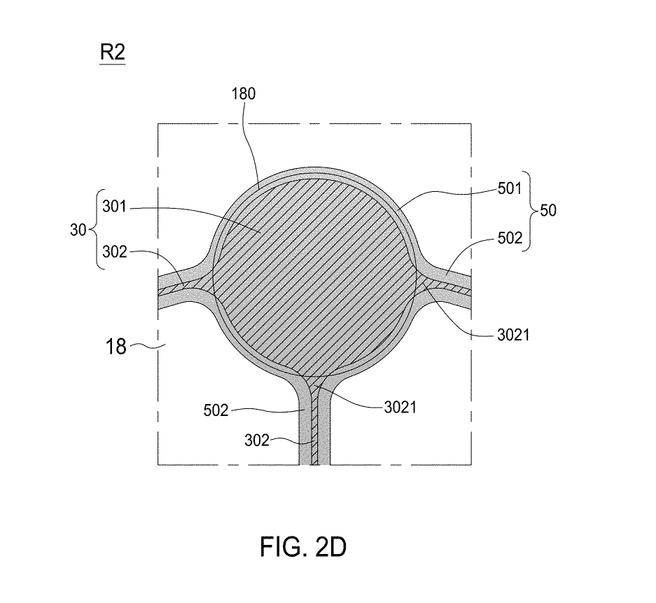

FIG. 1 shows a top view of a light-emitting device 1 in accordance with the first embodiment of the present application; FIG. 2A shows a cross-sectional view taken along line A-A′ of the light-emitting device 1 in FIG. 1; FIG. 2B shows a cross-sectional view taken along line B-B′ of the light-emitting device 1 in FIG. 1; FIG. 2C shows an enlarged view of a partial area R1 of the light-emitting device 1 in FIG. 1; and FIG. 2D shows an enlarged view of a partial area R2 of the light-emitting device 1 in FIG. 1.

As shown in FIG. 1 and FIGS. 2A-2C, the light-emitting device 1 includes a substrate 10, a semiconductor stack 12 on the substrate 10, a first and a second current blocking regions 40 and 50 on the semiconductor stack 12, a transparent conductive layer 18 on the semiconductor stack 12, a first electrode 20, a second electrode 30, and a protective layer (not shown) having openings to expose the first electrode 20 and the second electrode 30. The first electrode 20 includes a first pad electrode 201 and one or more first finger electrodes 202. The second electrode 30 includes a second pad electrode 301 and one or more second finger electrodes 302. The first finger electrodes 202 extend from the first pad electrode 201 toward the second pad electrode 301. The second finger electrodes 302 extend from the second pad electrode 301 toward the first pad electrode 201.

In this embodiment, the second electrode 30 includes three second finger electrodes 302 extending from the second pad electrode 301. The first electrode 20 includes two first finger electrodes 202 extending from the first pad electrode 201. The first pad electrode 201 and the second pad electrode 301 are respectively disposed near two opposite edges of the light-emitting device 1. One of the second finger electrodes 302 extends in a direction parallel with an edge between the two opposite edges of the light-emitting device 1 and is disposed between the two first finger electrodes 202. The two first finger electrodes 202 are disposed between the second finger electrodes 302 respectively.

In another embodiment, the first electrode 20 and the second electrode 30 include less or more finger electrodes.

In another embodiment, one of the first electrode 20 and the second electrode 30 includes the pad electrode without finger electrode extending therefrom.

The substrate 10 can be a growth substrate, for example, gallium arsenide (GaAs) wafer for growing aluminum gallium indium phosphide (AlGaInP), sapphire (Al₂O₃) wafer, gallium nitride (GaN) wafer or silicon carbide (SiC) wafer for growing indium gallium nitride (InGaN). The substrate 10 can be a patterned substrate with a patterned structure; i.e. the upper surface of the substrate 10 on which the semiconductor stack 12 is epitaxial grown can be patterned. Lights emitted from the semiconductor stack 12 can be refracted by the patterned structure of the substrate 10 so that the brightness of the LED is improved. Furthermore, the patterned structure retards or restrains the dislocation due to lattice mismatch between the substrate 10 and the semiconductor stack 12, so that the epitaxy quality of the semiconductor stack 12 is improved.

In an embodiment of the present application, the semiconductor stack 12 can be formed on the substrate 10 by organic metal chemical vapor deposition (MOCVD), molecular beam epitaxy (MBE), hydride vapor deposition (HVPE), or ion plating, such as sputtering or evaporation.

The semiconductor stack 12 includes a first semiconductor layer 121, an active layer 123 and a second semiconductor layer 122 sequentially formed on the substrate 10. In an embodiment of the present application, the first semiconductor layer 121 and the second semiconductor layer 122, such as a cladding layer or a confinement layer, have different conductivity types, electrical properties, polarities, or doping elements for providing electrons or holes. For example, the first semiconductor layer 121 is an n-type semiconductor, and the second semiconductor layer 122 is a p-type semiconductor. The active layer 123 is formed between the first semiconductor layer 121 and the second semiconductor layer 122. The electrons and holes combine in the active layer 123 under a current driving to convert electric energy into light energy to emit a light. The wavelength of the light emitted from the light-emitting device 1 or the semiconductor stack 12 is adjusted by changing the physical and chemical composition of one or more layers in the semiconductor stack 12.

The material of the semiconductor stack 12 includes a group III-V semiconductor material, such as AlₓIn_{y}Ga_{(1-x-y)}N or AlₓIn_{y}Ga_{(1-x-y)}P, wherein 0≤x, y≤1; (x+y)≤1. According to the material of the active layer, when the material of the semiconductor stack 12 is AlInGaP series material, red light having a wavelength between 610 nm and 650 nm or yellow light having a wavelength between 550 nm and 570 nm can be emitted. When the material of the semiconductor stack 12 is InGaN series material, blue or deep blue light having a wavelength between 400 nm and 490 nm or green light having a wavelength between 490 nm and 550 nm can be emitted. When the material of the semiconductor stack 12 is AlGaN series material, UV light having a wavelength between 400 nm and 250 nm can be emitted. The active layer 123 can be a single heterostructure (SH), a double heterostructure (DH), a double-side double heterostructure (DDH), or a multi-quantum well structure (MQW). The material of the active layer 123 can be i-type, p-type, or n-type semiconductor.

Besides, a buffer layer (not shown) is formed between the upper surface of the substrate 10 and the first semiconductor layer 121. The buffer layer also reduces the lattice mismatch described above and restrains the dislocation so as to improve the epitaxy quality. The material of the buffer layer includes GaN, AlGaN or AlN. In one embodiment, the buffer layer includes a plurality of sub-layers (not shown). The sub-layers include the same material or different material. In one embodiment, the buffer layer includes two sub-layers. The sub-layers include same material AlN. The growth method of the first sub-layer of the two sub-layers is sputtering, and the growth method of the second sub-layers of the two sub-layers is MOCVD. In one embodiment the buffer layer further includes a third sub-layer. The growth method of the third sub-layers is MOCVD, and the growth temperature of the second sub-layer is higher than or lower than that of the third sub-layer.

An exposed region 28 is formed by etching and removing parts of the second semiconductor layer 122 and the active layer 123 downward to an upper surface of the first semiconductor layer 121. The side surfaces of the second semiconductor layer 122 and the active layer 123 and the upper surface of the first semiconductor layer 121 are exposed. The first electrode 20 is disposed on the exposed upper surface of the first semiconductor layer 121 to form an electrical connection with the first semiconductor layer 121. The second electrode 30 is disposed on the second semiconductor layer 122 to form an electrical connection with the second semiconductor layer 122.

The first current blocking region 40 are formed between the first electrode 20 (the first pad electrode 201 and/or the first finger electrodes 202) and the first semiconductor layer 121, and the second current blocking region 50 is formed between the second electrode 30 (the second pad electrode 301 and/or the second finger electrodes 302) and the second semiconductor layer 122. Current is injected into the light-emitting device 1 via the first pad electrode 201 and the second pad electrode 301 and flows into the second finger electrodes 302, and then spreads in the transparent conductive layer 18 and the second semiconductor layer 122. The first current blocking region 40 and the second current blocking region 50 prevent most parts of the current from directly flowing into the active layer 123 under the electrodes. That is, the injected current is prevented from directly flowing downward at the electrode regions.

In the embodiment, as shown in FIG. 1, the first current blocking region 40 includes a first core region 401 under the first pad electrode 201 and a plurality of separated islands 402 under the first finger electrodes 202. The second current blocking region 50 includes a second core region 501 under the second pad electrode 301, and a plurality of extending regions 502 extending from the second core region 501 and under the second finger electrodes 302. At regions of the first pad electrode 201 and the second pad electrode 301, the current (electron or hole) is blocked from flowing downward via the first core region 401 and the second core region 501. The current, spread in the first finger electrodes 202, is blocked from flowing downward via the plurality of separated islands 402, and flows into the first semiconductor layer 121 through regions between two adjacent islands 402. The current, spread in the second finger electrodes 302 flows into the transparent conductive layer 18 and is blocked from flowing downward via the plurality of extending regions 502 under the second finger electrodes 302, and then the current is spread laterally in the transparent conductive layer 18 and uniformly flow into the semiconductor stack 12.

The material of the first and the second current blocking regions 40 and 50 includes transparent insulated material, such as silicon oxide, silicon nitride, silicon oxynitride, titanium oxide or aluminum oxide, etc. The structure of the current blocking region can be a single layer or alternately multiple layers, such as DBR (distributed Bragg reflector). The thickness of the first current blocking region 40 and the second current blocking region 50 ranges from 700-5000 Å. In one embodiment, the thickness of the first current blocking region 40 and the second current blocking region 50 ranges from 700-1000 Å. In another embodiment, the thickness of the first current blocking region 40 and the second current blocking region 50 ranges from 1000-5000 Å.

The transparent conductive layer 18 is formed on the second current blocking region 50 and the top surface of the second semiconductor layer 122, so that the current injected into the second electrode 30 can be spread uniformly by the transparent conductive layer 18 and then flow into the second semiconductor layer 122. Because the transparent conductive layer 18 is disposed on the light extraction side of the light-emitting device 1, an electrically-conducting material that has transparent property is preferable to be selected. More specifically, the transparent conductive layer 18 may include thin metal film. The material of the thin metal film can be Ni or Au. The material of the transparent conductive layer 18 includes oxide containing at least one element selected from zinc, indium, or tin, such as ZnO (zinc oxide), InO (indium oxide), SnO (tin oxide), ITO (indium tin oxide), IZO (indium zinc oxide), or GZO (gallium-doped zinc oxide).

As shown in FIG. 1, the second current blocking region 50 has a larger area than that of the second electrode 30. The extending region 502 of the second current blocking region 50 is disposed along the second finger electrodes 302 and has a width larger than that of the second finger electrodes 302. The contour of the second current blocking region 50 exceeds the contour of the second electrode 30 by 1-10 μm.

The transparent conductive layer 18 includes an opening 180 exposing the second core region 501 of the second current blocking region 50. In this embodiment, the width of the opening 180 of the transparent conductive layer 18 is smaller than the width of the second core region 501 and larger than the width of the second pad electrode 301. The transparent conductive layer 18 covers the top surface of the second semiconductor layer 122, the extending regions 502 of the second current blocking region 50 and partial top surface of the second core region 501. Because the width of the opening 180 of the transparent conductive layer 18 is larger than the width of the second pad electrode 301, the transparent conductive layer 18 does not contact the second pad electrode 301. In one embodiment, as shown in FIG. 2A, a distance D between an edge of the second core region 501 and the opening 180 ranges from 1 to 10 μm. Since the whole bottom area of the second pad electrode 301 contacts the second core region 501 of the second current blocking region 50, and adhesion between the second pad electrode 301 and the second current blocking region 50 is stronger than that between the second pad electrode 301 and the transparent conductive layer 18. The second pad electrode 301 is prevented from peeling off the light-emitting device 1. The yield and reliability of the light-emitting device are improved. Furthermore, the transparent conductive layer 18 that does not contact the second pad electrode 301 can further prevent current directly flow into the second semiconductor layer 122 adjacent to the second pad electrode 301 via the contact between the transparent conductive layer 18 and the second pad electrode 301. In other words, the light cannot be emitted by the semiconductor stack 12 adjacent to the second pad electrode 301, and the current can be efficiently used.

As shown in FIG. 2D, the enlarged view of the area R2 of the light-emitting device 1, the second finger electrode 302 includes a first portion 3021 extending from the periphery of the second pad electrode 301 and formed above the second current blocking region 50 and the transparent conductive layer 18. The first portion 3021 extends beyond the opening 180 of the transparent conductive layer 18. A part of the first portion 3021 is formed in the opening 180 of the transparent conductive layer 18 and connects another part of the first portion 3021 formed on the transparent conductive layer 18. The width of the first portions 3021 is wider than other portion of the second finger electrode 302.

As shown in FIG. 1 an FIG. 2A, The first core region 401 of the first current blocking region 40 has a larger area than that of the first pad electrode 201. The contour of the first core region 401 exceeds the contour of the first pad electrode 201 by 3-15 μm. The plurality of separated islands 402 are disposed along the first finger electrodes 202. Each island 402 has a width larger than that of the first finger electrodes 202. As shown in FIG. 2B, the island 402 does not contact the side surfaces of the second semiconductor layer 122 and the active layer 123 in the exposed region 28. In one embodiment, a spacing S between the island 402 and the side surface of the exposed region 28 is not smaller than 1 μm. The plurality of separated islands 402 is distributed on the first semiconductor layer 121 and the first finger electrodes 202 only contact the first semiconductor layer 121 not covered by the islands 402. Therefore, current is prevented from crowding in local region in the semiconductor stack 12 near the first core region 401. Current spreading in the semiconductor stack 12 is improved. Besides, the islands 402 are composed of transparent insulated material and the side surfaces of the islands 402 are inclined in a cross sectional view. In this way, the side surfaces of the islands 402 benefit light extraction. Moreover, when the spacing S between the island 402 and the side surface of the exposed region 28 is not smaller than 1 μm, light will escape from the semiconductor stack 12 more easily. In one embodiment, the island 402 includes a round corner or round edge in a top view. The round corner or round edge of the island 402 is also helpful for light extraction.

FIG. 2C shows an enlarged view of the partial area R1 in the light-emitting device 1. As shown in FIG. 2C, the first finger electrode 202 includes a first portion 2021 extending from the periphery of the first pad electrode 201 and extending beyond the periphery of the current blocking region 401. In other words, the first portion 2021 of the first finger electrode 202 is formed on a region of the first core region 401 near the periphery of the first core region 401 and a region of the first semiconductor layer 121. One part of the first portion 2021 formed on the region of the first core region 401 includes a larger surface area than that of another part of the first portion 2021 formed on the region of the first semiconductor layer 121 from the top view of the light-emitting device 1 or the side view of the light-emitting device 1. The width of the first portions 2021 is wider than other portion of the first finger electrode 202.

The first portion 2021 of the first finger electrode 202 and the first portion 3021 of the second finger electrode 302 including wider widths and larger areas can allow higher current pass through to avoid electrostatic discharge (ESD) or Electrical Over Stress (EOS) damage.

As shown in FIG. 2C, D1 indicates the shortest distance between the first core region 401 and the island 402 which is most closed to the first core region 401 (i.e. the first island 402a), and D2 indicates the shortest distance between two adjacent islands 402. In this embodiment, D1 is not greater than D2.

In one embodiment, the distance D2 between each two adjacent islands 402 is substantially equal. In another embodiment, the distance between each two adjacent islands 402 increases as along the island 402 is disposed far away from the first pad electrode 201. That is, while the island 402 is disposed more far away from the first pad electrode 201, the distance between two adjacent islands 402 is greater.

In another embodiment, the total length of all the islands 402 under one first finger electrode 202 is L_{island} and the length of the one first finger electrode 202 is L_{finger}; the ratio L_{island}/L_{finger} ranges from 20%-80%.

In another embodiment, an end of the first finger electrode 202 contacts the first semiconductor layer 121 without the islands 402 formed therebetween.

In another embodiment, the first finger electrode 202 and the second finger electrode 302 have different widths form a top view. For example, the first finger electrode 202 is wider than the second finger electrode 302.

In another embodiment, the extending region 502 of the second current blocking region 50 and the island 402 of the first current blocking region 40 have different widths from a top view. For example, the extending region 502 of the second current blocking region 50 is wider than the island 402 of the first current blocking region 40.

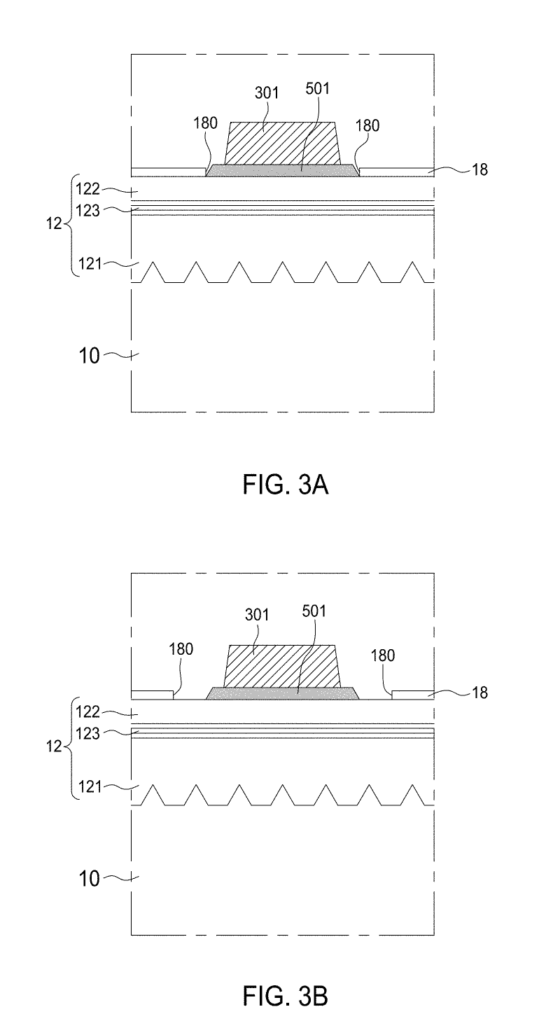

FIGS. 3A and 3B respectively show cross-sectional views taken along line C-C′ of the light-emitting device 1 in FIG. 1, in accordance with different embodiments of the present application. The difference between the different embodiments and the first embodiment is the width of the opening 180 of the transparent conductive layer 18. As shown in FIG. 3A, the width of the opening 180 of the transparent conductive layer 18 is substantially equal to the width of the second core region 501. The transparent conductive layer 18 does not contact the top surface of the second core region 501 of the second current blocking region 50. As shown in FIG. 3B, the width of the opening 180 of the transparent conductive layer 18 is larger than the width of the second core region 501. The transparent conductive layer 18 neither contacts the top surface nor the side surface of the second core region 501.

### Second Embodiment

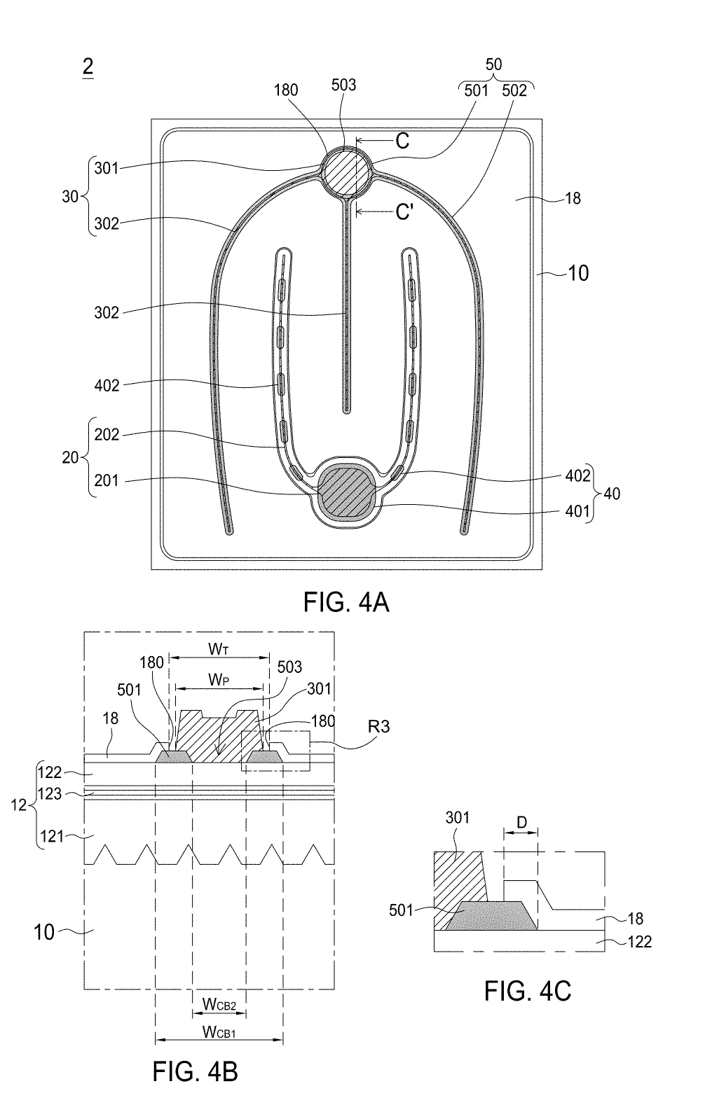

FIG. 4A shows a top view of a light-emitting device 2 in accordance with the second embodiment of the present application. FIG. 4B shows a cross-sectional view taken along line C-C′ of the light-emitting device 2 in FIG. 4A. The structure of the light-emitting device 2 is similar with that described in the first embodiment. The difference is, the second core region 502 of the second current blocking region 50 includes an opening 503 under the second pad electrode 301. The second pad electrode 301 contacts the second semiconductor layer 122 via the opening 503. The transparent conductive layer 18 covers the top surface of the second semiconductor layer 122, the extending regions 502 of the second current blocking region 50 and a partial top surface of the second core region 501. As shown in FIG. 4B, the width W_{T} of the opening 180 of the transparent conductive layer 18 is smaller than the outer width W_{CB1} of the second core region 502 and greater than the width W_{CB2} of the opening 503 of the second core region 501 so that the transparent conductive layer 18 covers side surface and a partial top surface of the second core region 501. Besides, W_{T} is larger than the width W_{P} of the second pad electrode 301 so that the transparent conductive layer 18 does not contact the second pad electrode 301. FIG. 4C is an enlarged view of the partial region R3 of FIG. 4B. In one embodiment, a distance D between an outer edge of the second core region 501 and the opening 180 ranges from 1 to 10 μm.

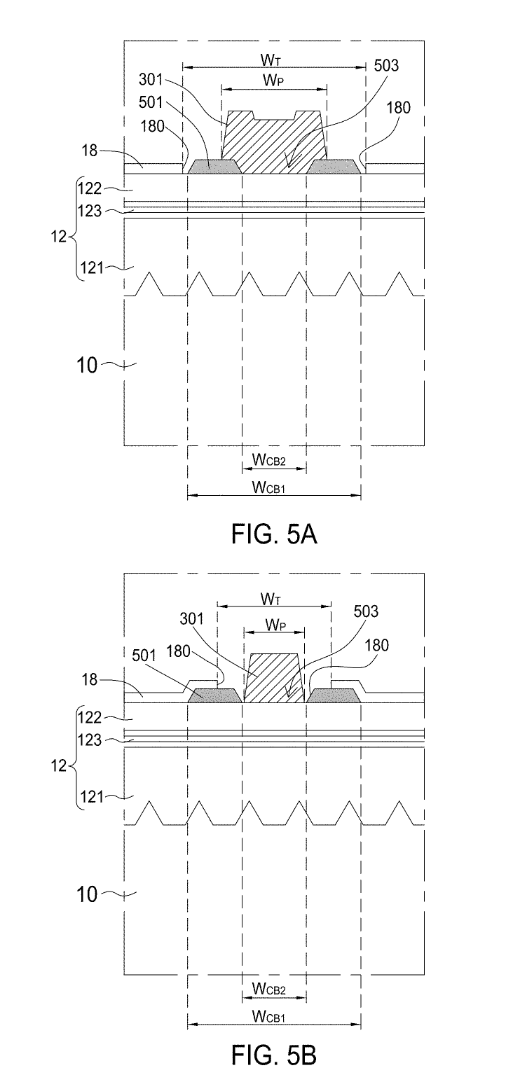

FIGS. 5A and 5B respectively show cross-sectional views taken along line C-C′ of the light-emitting device 2 in FIG. 4A, in accordance with different embodiments of the present application. The difference between the different embodiments and the second embodiment is the width of the opening 180 of the transparent conductive layer 18. As shown in FIG. 5A, the width W_{T} of the opening 180 of the transparent conductive layer 18 is substantially equal to or larger than the width W_{CB1} of the second core region 501. The transparent conductive layer 18 does not contact the top surface of the second core region 501. As shown in FIG. 5B, the width W_{P} of the second pad electrode 301 is not larger than or substantially equal to the width W_{CB2} of opening 503 of the second core region 501. The second pad electrode 301 contacts neither the transparent conductive layer 18 nor the top surface of the second core region 501.

In the embodiments shown in FIGS. 5A and 5B, the whole bottom area of the second pad electrode 301 contacts the second core region 501 and/or the second semiconductor layer 122, and adhesion between the second pad electrode 301 and the second current blocking region 50 (501) and/or the second semiconductor layer 122 is stronger than that between the second pad electrode 301 and the transparent conductive layer 18, and then the second pad electrode is prevented from peeling off the light-emitting device. The yield and reliability of the light-emitting device are improved.

### Third Embodiment

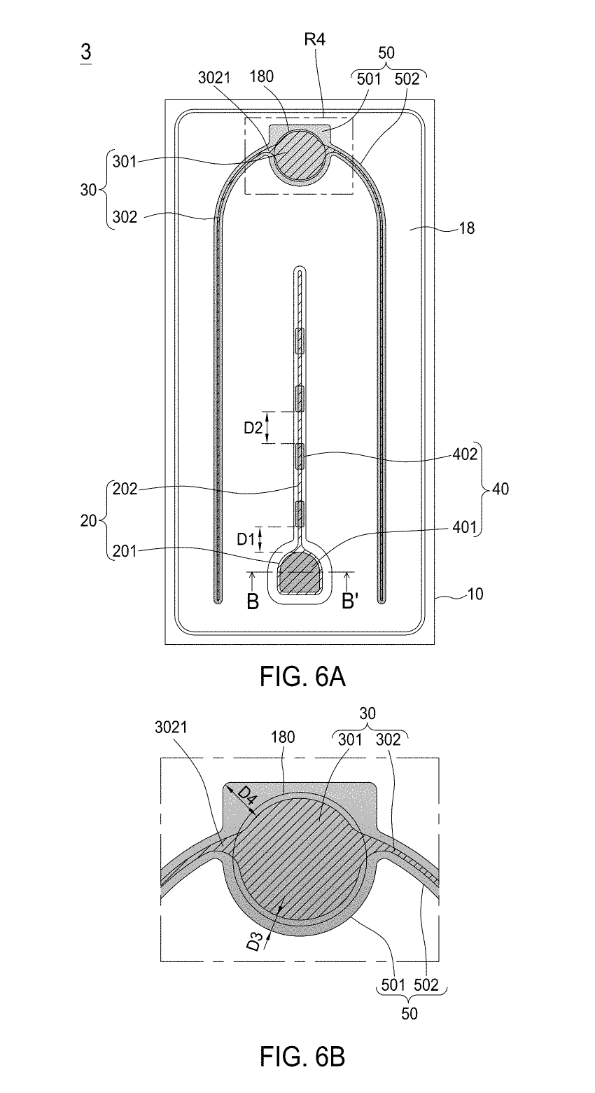

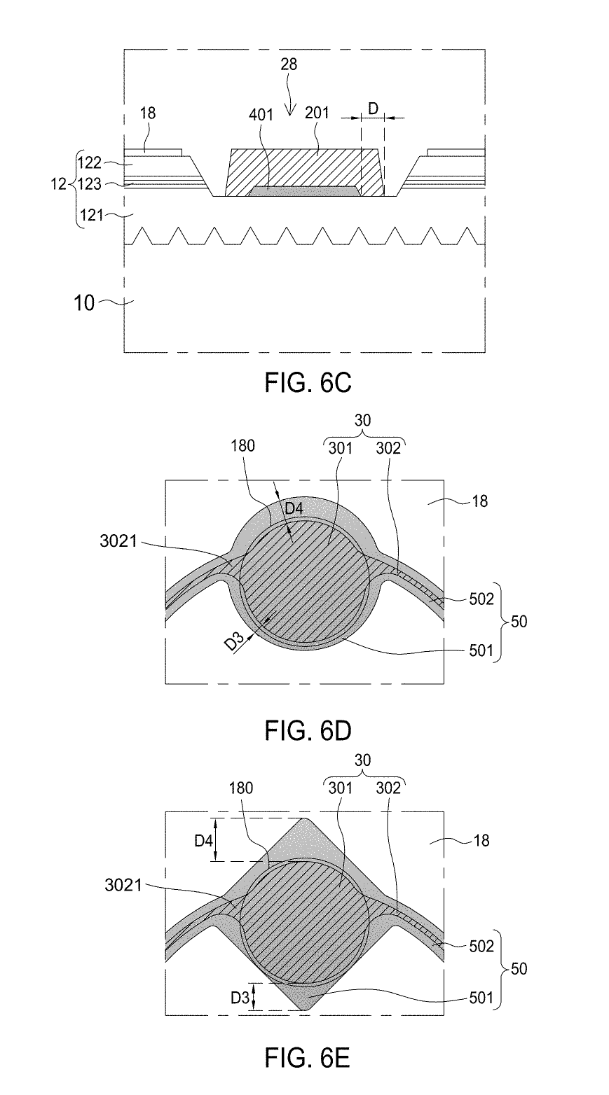

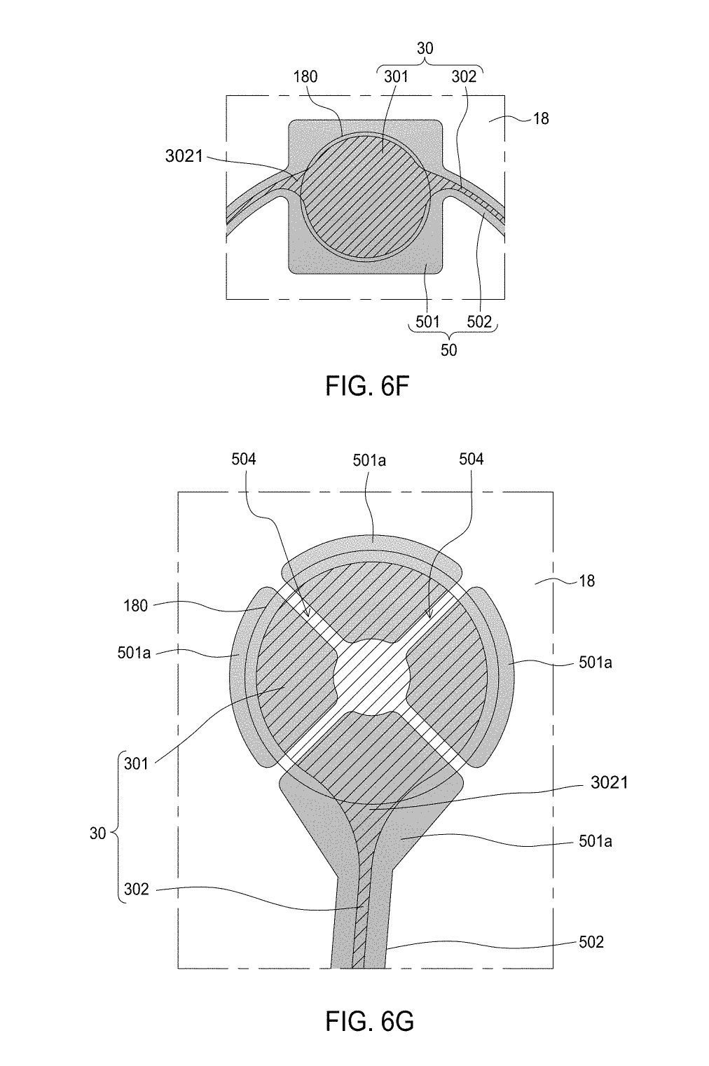

FIG. 6A shows a top view of the light-emitting device 3 in accordance with the third embodiment of the present application. FIG. 6B shows an enlarged view of the partial region R4 of FIG. 6A. FIG. 6C shows a cross-sectional view taken along line B-B′ of the light-emitting device 3 in FIG. 6A.

As shown in FIG. 6A, the light-emitting device 3 includes a substrate 10, a semiconductor stack 12 on the substrate 10, a first and a second current blocking regions 40 and 50 on the semiconductor stack 12, a transparent conductive layer 18 on the semiconductor stack 12, a first electrode 20, a second electrode 30, and a protective layer (not shown) having openings to expose the first electrode 20 and the second electrode 30. The structure of the light-emitting device 3 is similar with that described in the first embodiment. The differences between the light-emitting device 3 and the light-emitting device 1 are described as below.

In this embodiment, the second electrode 30 includes two second finger electrodes 302 extending from the second pad electrode 301. The first electrode 20 includes one first finger electrode 202 extending from the first pad electrode 201. The first pad electrode 201 and the second pad electrode 301 are disposed near two opposite edges of the light-emitting device 3. The first finger electrode 202 extends in a direction parallel with an edge connecting the two opposite edges of the light-emitting device 3 and is disposed between the two second finger electrodes 302.

The first current blocking region 40 includes a first core region 401 under the first pad electrode 201 and a plurality of separated islands 402 under the first finger electrode 202. The second current blocking region 50 includes a second core region 501 under the second pad electrode 301 and a plurality of extending regions 502 extending from the second core region 501 and under the second finger electrodes 302.

As shown in FIG. 6C, the first core region 401 of the first current blocking region 40 has a width smaller than that of the first pad electrode 201. Therefore, the first pad electrode 201 directly contacts an area of the first semiconductor layer 201 outside of the first core region 401. The contour of the first pad electrode 201 exceeds the contour of the first core region 401 more than 2 μm. That is, a distance D between the edges of the first pad electrode 201 and the first core region 401 is more than 2 μm to assure a sufficient contact area between the first pad electrode 201 and the first semiconductor layer 121 for current injection. In one embodiment, D ranges from 2-15 μm. In the cross-sectional view, a slope of a side surface of the first pad electrode 201 is greater than a slope of a side surface of the first core region 401. The gentler slope of a side surface of the first core region 401 can improve the yield and the reliability of the following process of the first pad electrode 201.

The first core region 401 of the first current blocking region 40 below the first pad electrode 201 prevents the current from being directly injected into the semiconductor layer under the pad electrode, so that the current is forced to spread laterally. Another advantage that a light emitting device with a current blocking region is that light emitted from the active layer can be extract by the current blocking region and then brightness of the light emitting device can be improved. However, a larger blocking region means a less contact area between electrodes and the semiconductor stack, and then the electric characteristics might be affected, such as forward voltage (Vf) of the light emitting device. The area, position or layout of the current blocking region is a tradeoff according to brightness and electric characteristics of the light emitting device. As shown in the first embodiment, the light-emitting device has the semiconductor stack 12 with a larger area, and then a plurality of first finger electrodes 202 are chosen to satisfy the current spreading purpose in the semiconductor stack 12 with the larger area, and the first core region 401 which has a larger area than that of the first pad electrode 201 benefits brightness. As shown in the third embodiment, the light-emitting device 3 has the semiconductor stack 12 with smaller area and less first finger electrodes, for example, a single first finger electrode 202, setting the first core region 401 to have an area smaller than that of the first pad electrode 201 increases the contact area between the first semiconductor layer 121 and the first electrode 20, so that the forward voltage (Vf) can be decreased.

In one embodiment, the first core region 401 and the first pad electrode 201 have different shapes as shown in FIG. 8A. In another embodiment, the first core region 401 and the first pad electrode 201 have similar shapes, and the first pad electrode 201 are rotated anticlockwise in several degrees, such as 30 degrees, as shown in FIG. 8B. In FIG. 8A and FIG. 8B, a part of the first core region 401 has a periphery beyond the periphery of the first pad electrode 201, and another part of the first core region 401 has a periphery behind the periphery of the first pad electrode 201. The part of the first core region 401 having the periphery beyond the periphery of the first pad electrode 201 can be a protrusion or plurality protrusions. The first pad electrode 201 partially contacts the first semiconductor layer 121 and current can be blocked by the part of the first core region 401 having a periphery beyond the periphery of the first pad electrode 201.

As shown in FIG. 6A, D1 indicates the shortest distance between the first core region 401 and the island 402 which is most closed to the first core region 401, and D2 indicates the shortest distance between two adjacent islands 402. In this embodiment, D1 is not greater than D2. In one embodiment, D1 is smaller than D2.

In this embodiment, as shown in FIG. 6B, the second core region 501 and the second pad electrode 301 have different shapes in top view. That is, an outer contour of the second core region 501 and the second pad electrode 301 are not similar. For example, the second pad electrode 301 is a circle and the outer contour of the second core region 501 is an ellipse, square, rectangle, rounded rectangle as shown in FIG. 6E, rhombus, trapezoid, polygon or any other shape with protrusions. In one embodiment, the distance between the outer contour of the second core region 501 and the second pad electrode 301 does not remain equal. For example, as shown in FIG. 6B, the second pad electrode 301 is a circular shape and the second core region 501 is a polygonal shape. A first part of the contour of the second core region 501, i.e. the part which faces the first electrode 20, is an arc. A second part of the contour of the second core region 501, i.e. the part which is distant from the first electrode 20, has a periphery of a part of a rectangle composed by three lines. A distance between the first part of contour of the second core region 501 and the second pad electrode 301 is D3, and a distance between the second part of contour of the second core region 501 and the second pad electrode 301 is D4. D3 is smaller than D4. As a result, a current blocking region at the side facing the first electrode 20 is smaller than that at the side distant from the first electrode 20. The efficient light emission region of the semiconductor stack 12 is between the first electrode 20 and second electrode 30 caused by current spreading between the first electrode 20 and second electrode 30. In order to block current flowing to regions not between the first electrode 20 and second electrode 30, especially the region between the second pad electrode 301 and the adjacent edge of the light-emitting device 3, the second core region 501 between the second pad electrode 301 and the adjacent edge of the light-emitting device 3 includes a larger area than that of the second core region 501 at the side facing the first electrode 20. Current from the second pad electrode 301 tends to flow toward the first electrode 20 more easily.

In another embodiment, the second extending region 502 and the second finger electrode 302 have different shapes in top view.

FIGS. 6D-6F respectively show different designs for the second electrode 30 and the second blocking region 50, in accordance with different embodiments of the present application. In FIGS. 6D and 6E, D3 is smaller than D4.

In one embodiment, the second core region 501 of the second current blocking region 50 includes an opening (not shown) exposing the second semiconductor layer 122, as described in the second embodiment. In one embodiment, the opening of the second core region 501 has a shape the same as the shape of the second core region 501. For example, a shape of the second core region 501 is a circle as shown in FIG. 6D, and a shape of the opening of the second core region 501 is also a circle. In one embodiment, the opening of the second core region 501 has a shape different from the shape of the second core region 501. For example, a shape of the second core region 501 is a rounded rectangle as shown in FIG. 6F, and a shape of the opening of the second core region 501 is a circle (not shown).

FIG. 6G shows an enlarged view of partial areas of the second electrode 30 and the second current blocking region 50 of a light-emitting device in accordance with another embodiment of the present application. The structure of the light-emitting device in FIG. 6G is similar to that of the light-emitting device 3. The differences between the light-emitting device in FIG. 6G and the light-emitting device 3 are electrode layout and the second current blocking region 50. As shown in FIG. 6G, the second core region 501 (501a) and the second pad electrode 301 have different shapes in top view. The second core region 501 of the second current blocking region 50 includes a plurality of islands 501a separated with each other by slits 504. The transparent conductive layer 18 covers the extending region 502 and parts of the second core region 501 of the second current blocking region 50 and includes an opening 180 exposing a portion of top surfaces of the islands 501a. The second pad electrode 301 is formed on the plurality of islands 501a and contacts the second semiconductor layer 122 via the slits 504. In one embodiment, the extending region 502 of the second current blocking region 50 connects to one of the island 501a as shown in FIG. 6G. In another embodiment, the extending region 502 of the second current blocking region 50 is divided from the second core region 501.

### Fourth Embodiment

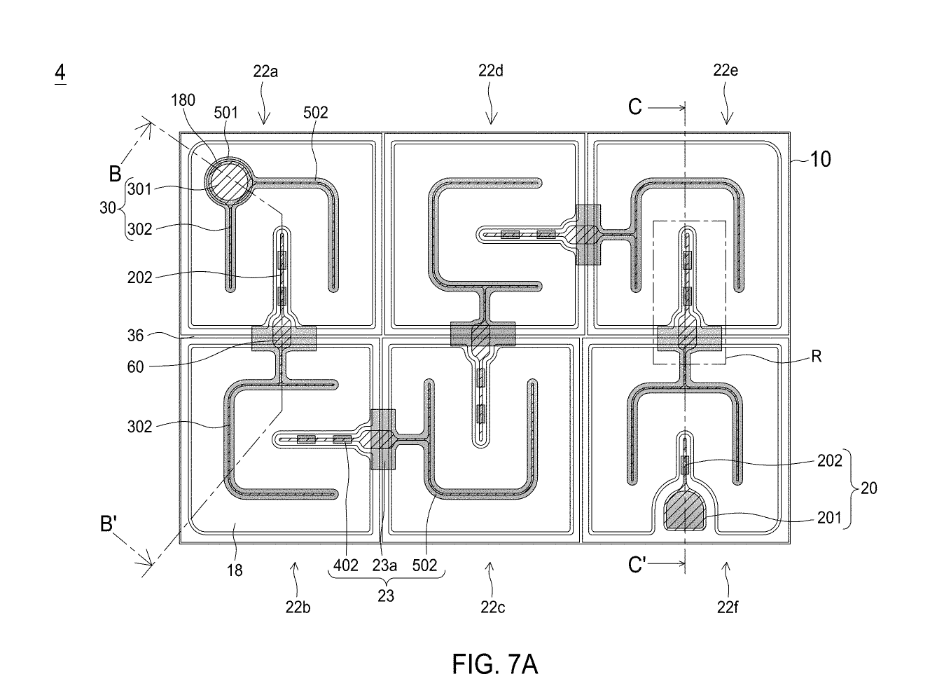

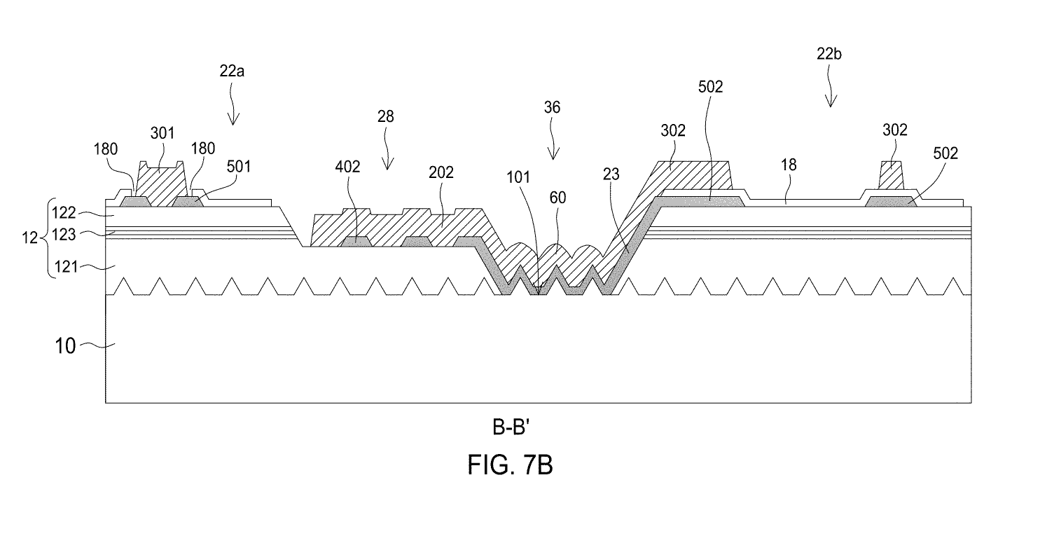

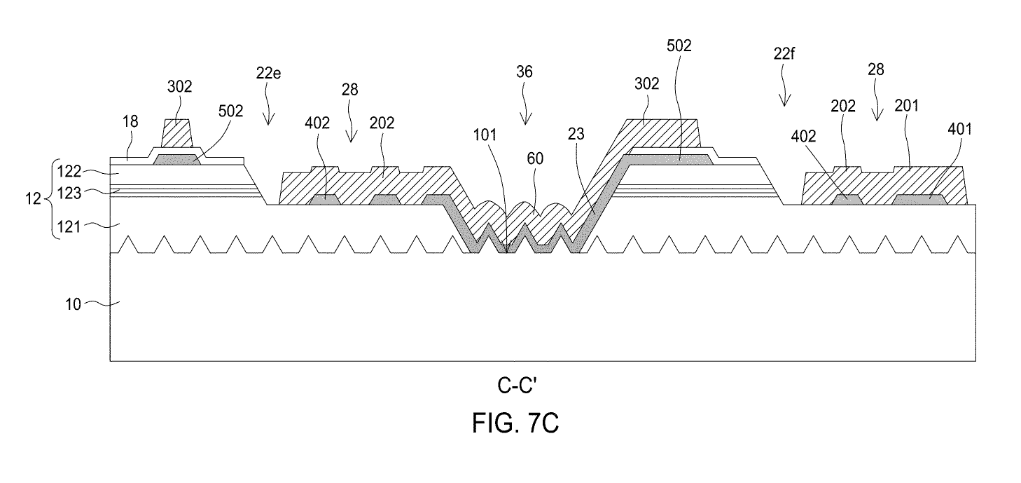

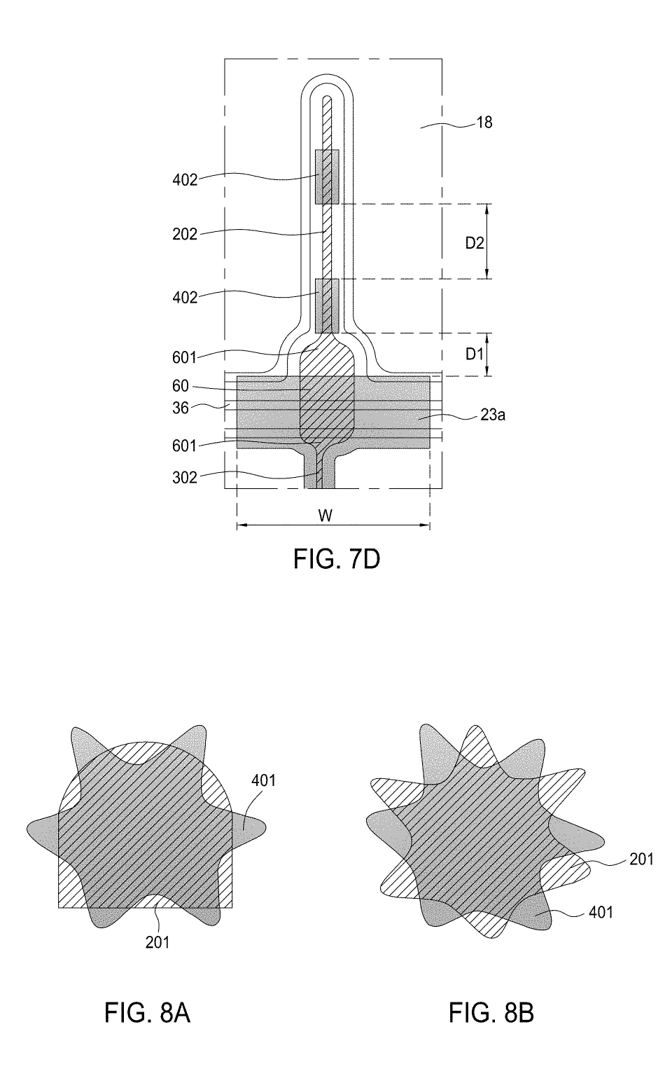

FIGS. 7A-7D show a light-emitting device 4 in accordance to a fourth embodiment of the present application. In the embodiment, the light-emitting device 4 is a light-emitting diode array. FIG. 7A shows a top view of the light-emitting device 4. FIG. 7B and FIG. 7C respectively show cross-sectional views taken along line B-B′ and line C-C′ of the top view in FIG. 7A. FIG. 7D shows an enlarged view of a partial area R of the top view in FIG. 7A.

The light-emitting device 4 includes a substrate 10 and a plurality of light-emitting units 22 (22a-22f) formed on the substrate 10 and arranged in a two-dimensional array. Each light-emitting unit 22 includes a semiconductor stack 12. The plurality of light-emitting units 22 electrically connects in series via connecting electrodes 60, first finger electrodes 202 and second finger electrodes 302 formed thereon.

The manufacturing method of the light-emitting device 4 is described as below. The semiconductor stack 12 is formed on a substrate 10 by epitaxy process. Then, as shown in FIG. 7B and FIG. 7C, a portion of the semiconductor stack 12 is selectively removed by etching process to expose the first surface 101 of the substrate 10. The exposed first surfaces 101 and the side surfaces between the adjacent semiconductor stacks 12 form trenches 36 so that the plurality of semiconductor stacks 12 of the light-emitting units 22 are separately arranged on the substrate 10. An exposed regions 28 of each light-emitting unit 22 is formed by photolithography and etching process so that the exposed region 28 serves as a platform for forming pads for connecting outside power providing current or other electronic components, or forming electrodes which spread the injected current and/or electrically connect the adjacent units thereon.

In another embodiment, in order to increase light-extraction efficiency or heat dispersion efficiency of the light-emitting device, the semiconductor stack 12 of the light-emitting unit 22 can be disposed on the substrate 10 by wafer transferring and wafer bonding. The wafer bonding method includes direct bonding or indirect bonding. Direct bonding can be fusion bonding or anodic bonding, etc. In indirect bonding, the semiconductor stack 12 of the light-emitting unit 22 is epitaxial grown on an epitaxial substrate (not shown), and then is bonded with the substrate 10 by adhering, heating or pressuring. The semiconductor stack 12 of the light-emitting unit 22 can be adhered to the substrate 10 by an inter-medium (not shown). The inter-medium can be a transparent adhesion layer, and it also can be replaced by a metal material. The transparent adhesion layer can be organic polymer transparent glue, such as polyimide, BCB (Benzocyclobutene), PFCB (Perfluorocyclobutyl), Epoxy, Acrylic resin, PET (Polyethylene terephthalate), PC (Polycarbonate) or combination thereof; or a transparent conductive oxide metal such as ITO, InO, SnO₂, ZnO, FTO (fluorine-doped tin oxide), ATO (antimony tin oxide), CTO (cadmium tin oxide), AZO (aluminum-doped zinc-oxide), GZO (gallium-doped zinc oxide) or combination thereof; or an inorganic insulator, such as SOG (spin-on-glass), Al₂O₃, SiNₓ, SiO₂, AlN, TiO₂, Ta₂O₅ or combination thereof. The metal material includes but is not limited to Au, Sn, In, Ge, Zn, Be, Pd, Cr, or alloy thereof such as PbSn, AuGe, AuBe, AuSn, PdIn, etc.

In fact, the method of forming the semiconductor stack 12 of the light-emitting unit 22 on the substrate 10 is not limited to these approaches. People having ordinary skill in the art can understand that the semiconductor stack 12 of the light-emitting unit 22 can be directly epitaxial grown on the substrate 10 according to different characteristics of the structures, such as optical and electrical properties, or productivity.

Next, an insulator 23 is disposed on the trenches 36 and continuously covers side surfaces and top surfaces of the semiconductor stack 12 of the light-emitting units 22. The insulator 23 includes a middle structure 23a covering a portion or all of the trench 36 between two adjacent light-emitting units 22. Parts of the insulator 23 which covers the top surface of the second semiconductor layer 122 is patterned to form a second core region 501 and extending regions 502 of the second current blocking region 50 as described in the above embodiments. The extending regions 502 connect to the middle structure 23a. Parts of the insulator 23 on the first semiconductor layer 121 is further patterned to form a first core region 401 and a plurality of separated islands 402 of the first current blocking region 40 as described in the above embodiments. The islands 402 are separated from the middle structure 23a. The functions of the plurality of separated islands 402 of the first current blocking region 40 and the extending region 502 of the second current blocking region 50 are the same as described in the above embodiments. The middle structure 23a of the insulator 23 formed in the trenches 36 and on the side surfaces of the light-emitting units 22 protects the semiconductor stacks 12 and electrically insulates the adjacent light-emitting units 22. The material of the insulator 23 includes transparent insulated material, such as silicon oxide, silicon nitride, silicon oxynitride, titanium oxide or aluminum oxide.

In one embodiment, the structures of the insulator 23 (the middle structure 23a, the second current blocking region 50 or the first current blocking region 40) can be a single layer or alternately multiple layers, such as DBR (distributed Bragg reflector).

In another embodiment, the plurality of separated islands 402 of the first current blocking region 40 is omitted.

In another embodiment, the first core region 401 of the first current blocking region 40 is omitted.

Then, the transparent conductive layer 18 is disposed on the second semiconductor layer 122 and covers the extending regions 502 of the second current blocking region 50. The transparent conductive layer 18 includes an opening 180 on the light-emitting unit 22a exposing the second core region 502. The material of the transparent conductive layer 18 includes a metal oxide material such as indium tin oxide (ITO), cadmium tin oxide (CTO), antimony tin oxide (ATO), indium zinc oxide (IZO), aluminum-doped zinc oxide (AZO), or zinc tin oxide (ZTO). A metal layer with a thickness that light can pass through also can be the transparent conductive layer 18.

Next, an electrode layer is formed on the light-emitting units 22 and the trenches 36. The electrode layer includes the first pad electrode 201 on the light-emitting units 22f, the second pad electrode 301 on the light-emitting units 22a, first finger electrodes 202 and second finger electrodes 302 formed on the light-emitting units 22a-22f, and connecting electrodes 60 formed between two adjacent light-emitting units 22 (22a and 22b, 22b and 22c, 22c and 22d, 22d and 22e, 22e and 22f). Each of the connecting electrodes 60 is formed on the trench 36 and connects the first finger electrode 202 on one light-emitting unit and the second finger electrodes 302 on the adjacent light-emitting units 22. Each connecting electrode 60 connecting the first finger electrode 202 and the second finger electrodes 302 electrically connects two adjacent light-emitting units 22 so that the light-emitting units 22 form a series light-emitting diode array. In the present embodiment, a width of each connecting electrode 60 is larger than that of the first finger electrodes 202 and the second finger electrodes 302 in top view.

As shown in FIG. 7D, the connecting electrode 60 includes tapered structures 601 linked to the first finger electrode 202 and the second finger electrode 302. As shown in FIGS. 7B and 7C, the connecting electrode 60 is formed on the insulator 23 in the trench 36 and covers the side surfaces and a part of the top surfaces of the two adjacent light-emitting units 22. The thickness of the connecting electrode 60 on the side surface of the light-emitting units 22 is smaller than that of the first finger electrodes 202 and/or the second finger electrodes 302. The connecting electrode 60 includes a width less than that of the middle structure 23a of the insulators 23 formed thereunder and larger than that of the first finger electrode 202 and/or the second finger electrode 302. In on embodiment, a part of the side surfaces of the light-emitting units 22 where the connecting electrodes 60 are formed on can have a slope gentler than slopes of other parts of the side surfaces of the light-emitting units 22. In another embodiment, the method of electrically connecting two adjacent light-emitting units 22 is not limited to what is described above. People having ordinary skill in the art can understand that connecting electrodes 60 may link first finger electrodes 202 or second finger electrodes 302 disposed on the semiconductor layers with same conductivity or different conductivity of the different light-emitting units 22, so that the light-emitting units 22 can be electrically connected in series or in parallel.

The structures of the first electrode 20, the first current blocking region 40, the second electrode 30, the transparent conductive layer 18 and the second current blocking region 50 described in the above embodiments can be applied in the light-emitting device 4. More specifically, the structures of the first pad electrode 201, the first core region 401 of the first current blocking region 40, the second pad electrode 301, the transparent conductive layer 18 and the second core region 501 of the second current blocking region 50 described in the above embodiments can be applied in the light-emitting device 4. For example, as shown in FIG. 7B, the width of the opening 180 of the transparent conductive layer 18 is smaller than the width of the second core region 501 and larger than the width of the second pad electrode 301. The transparent conductive layer 18 covers the top surface of the second semiconductor layer 122, the extending regions 502 of the second current blocking region 50 and a partial top surface of the second core region 501. Because the width of the opening 180 of the transparent conductive layer 18 is larger than the width of the second pad electrode 301, the transparent conductive layer 18 does not contact the second pad electrode 301.

Referring to FIG. 7C, the first core region 401 of the first current blocking region 40 is formed under the first pad electrode 201. The first core region 401 of the first current blocking region 40 has a width smaller than that of the first pad electrode 201. Therefore, the first pad electrode 201 directly contacts an area of the first semiconductor layer 201 outside of the first core region 401. In one embodiment, a slope of a side surface of the first pad electrode 201 is greater than a slope of a side surface of the first core region 401. The gentler slope of a side surface of the first core region 401 can improve the yield and the reliability of the following process of the first pad electrode 201.

As shown in FIG. 7D, D1 indicates the shortest distance between the middle structure 23a of the insulator 23 under the connecting electrode 60 and the island 402 of the first current clocking region 40 which is closest to the trench 36, and D2 indicates the shortest distance between two adjacent islands 402. In this embodiment, D1 is not greater than D2. In one embodiment, D1 is smaller than D2. In one embodiment, the island 402 is disposed under the first finger electrode 202 but not covered by the connecting electrode 60. In another embodiment, as shown in FIG. 7D, the islands 402 which is closest to the trench 36 extends to the tapered structure 601 of the connecting electrode 60. A part or parts of the islands 402 closest to the trench 36 is formed under the tapered structure 601.

The middle part 23a of the insulator 23 under the connecting electrode 60 has a width W larger than that of the connecting electrode 60. In one embodiment, W is larger than twice of the maximum width of the connecting electrode 60.

In one embodiment, a width of the middle structure 23a that exceeds the connecting electrode 60 is larger than a width of the extending region 502 of the second current blocking region 50 that exceeds the second finger electrode 302.

In another embodiment, one end of the middle part 23a of the insulator 23 connects to the extending region 502 of the second current blocking region 50 of one light-emitting unit 22, and the other end of the middle part 23a does not cover the side surface of the first semiconductor layer 121 of the adjacent light-emitting unit 22. The side surface of the first semiconductor layer 121 is exposed, and the connecting electrode 60 contacts the side surface of the first semiconductor layer 121 via the exposed side surface of the first semiconductor layer 121.

In another embodiment, the thickness of the middle part 23a of the insulator 23 on the side surface of each light-emitting unit 22 is smaller than that of the island 402 of the first current blocking region 40 and/or that of the extending region 502 of the second current blocking region 50.

In another embodiment, the first finger electrode 202 and the second finger electrode 302 have different widths from a top view. For example, the first finger electrode 202 is wider than the second finger electrode 302.

In another embodiment, the extending region 502 of the second current blocking region 50 and the island 402 of the first current blocking region 40 have different widths from a top view. For example, the extending region 502 of the second current blocking region 50 is wider than the island 402 of the first current blocking region 40.

The material of the first pad electrode 201, the first finger electrodes 202, the second pad electrode 301, the second finger electrodes 302 and the connecting electrodes 60 are preferably metal, such as Au, Ag, Cu, Cr, Al, Pt, Ni, Ti, Sn, Rh, alloy or stacked composition of the materials described above.

The light-emitting unit 22a can be the start unit of the electrical series and the light-emitting unit 22f can be the end unit of the electrical series. The light-emitting device 4 electrically connects to an external power or other circuits by wiring or soldering the first pad electrode 201 and the second pad electrode 301.

It will be apparent to those having ordinary skill in the art that various modifications and variations can be made to the devices in accordance with the present application without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a substrate;
a first semiconductor stack formed on the substrate, comprising a first semiconductor layer, a second semiconductor layer and an active layer formed therebetween;
a first electrode formed on the first semiconductor layer;
a second electrode formed on the second semiconductor layer, comprising a second pad electrode and a second finger electrode extending from the second pad electrode;
a second current blocking region formed under the second electrode, comprising a second core region under the second pad electrode and a extending region under the second finger electrode; and
a transparent conductive layer, formed on the second semiconductor layer and covering the extending region;
wherein a contour of the second core region has a shape different from that of the second pad electrode;
wherein the transparent conductive layer comprises a first opening having a width wider than a width of the second pad electrode,
wherein the second finger electrode comprises a portion extending from the contour of the second pad electrode and having a width wider than other portion of the second finger electrode, and part of the portion is not covered by the transparent conductive layer.

2. The light-emitting device of claim 1, wherein the transparent conductive layer does not contact the second pad electrode.

3. The light-emitting device of claim 1, wherein the second core region comprises a second opening and the second pad electrode contacts the second semiconductor layer via the second opening.

4. The light-emitting device of claim 1, wherein the second core region comprises a plurality of islands separated with each other by slits, and the second pad electrode is formed on the plurality of islands and contacts the second semiconductor layer via the slits.

5. The light-emitting device of claim 1, wherein the extending region of the second current blocking region connects to one of the plurality of islands.

6. The light-emitting device of claim 1, wherein the transparent conductive layer is formed on the second core region and a distance between an outer edge of the second core region and the first opening ranges from 1 to 10 μm.

7. A light-emitting device, comprising:
a substrate;
a first semiconductor stack formed on the substrate, comprising a first semiconductor layer, a second semiconductor layer and an active layer formed therebetween;
an exposed region formed in the first semiconductor stack, comprising a side surface and a bottom comprising an upper surface of the first semiconductor layer;
a first electrode formed in the exposed region and electrically connecting to the first semiconductor layer, comprising a first pad electrode and a first finger electrode extending from the first pad electrode; and
a first current blocking region formed under the first electrode, comprising a plurality of islands under the first finger electrode;
wherein a shortest distance between the side surface of the exposed region and one of the plurality of islands is not smaller than 1 μm.

8. The light-emitting device of claim 7, wherein the first current blocking region further comprises a first core region formed under the first pad electrode and the first core region is separated from the plurality of islands.

9. The light-emitting device of claim 8, wherein the first core region has an area smaller than that of the first pad electrode.

10. The light-emitting device of claim 7, wherein the plurality of islands comprises a last island which is closest to an end of the first finger electrode, and a distance between the last island and the end of the first finger electrode is larger than a shortest distance between two adjacent islands.

11. A light-emitting device, comprising:
a substrate;
a first semiconductor stack formed on the substrate, comprising a first semiconductor layer, a second semiconductor layer and an active layer formed therebetween;
an exposed region formed in the first semiconductor stack, comprising a bottom comprising an upper surface of the first semiconductor layer;
a first electrode formed in the exposed region and electrically connecting to the first semiconductor layer, comprising a first pad electrode; and
a first current blocking region formed under the first pad electrode;
wherein the first pad electrode contacts an area of the upper surface of the first semiconductor layer outside of the first current blocking region; and
wherein the first pad electrode comprises a first side surface and the first current blocking region comprises a second side surface, and wherein a slope of the first side surface is greater than a slope of the second side surface.

12. The light-emitting device of claim 8, wherein a distance between an edge of the first pad electrode and the first core region is more than 2

13. The light-emitting device of claim 11, wherein:
the first electrode further comprises a first finger electrode extending from the first pad electrode; and
the first current blocking region comprises a first core region formed under the first pad electrode and a plurality of islands formed under the first finger electrode; and
a shortest distance between the first core region and one of the plurality of islands which is most closed to the first core region is not greater than a shortest distance between two adjacent islands.

14. The light-emitting device of claim 11, wherein:
the first electrode further comprises a first finger electrode extending from the first pad electrode; and
the first current blocking region comprises a first core region formed under the first pad electrode and formed under the first finger electrode; and
one of the plurality of islands comprises a inclined side surface and a round corner.

15. The light-emitting device of claim 11, wherein:
the first current blocking region comprises a first core region formed under the first pad electrode; and
a part of the first core region has a periphery beyond a periphery of the first pad electrode, and another part of the first core region has a periphery behind the periphery of the first pad electrode.

16. The light-emitting device of claim 11, further comprising:
a second semiconductor stack formed on the substrate and spaced apart from the first semiconductor stack, comprising a first semiconductor layer, a second semiconductor layer and an active layer formed therebetween;
a first finger electrode formed on the first semiconductor layer of the second semiconductor stack;
a second finger electrode formed on the second semiconductor layer of the first semiconductor stack; and
a connecting electrode, connecting the first finger electrode on the second semiconductor stack and the second finger electrode on the first semiconductor stack;
wherein the connecting electrode comprises tapered structures linked to the first finger electrode on the second semiconductor stack and the second finger electrode on the first semiconductor stack.

17. The light-emitting device of claim 16, further comprising:
another first current blocking region comprising at least one island under the first finger electrode on the second semiconductor stack; and
wherein a part the island is formed under the tapered structure.

18. The light-emitting device of claim 11, further comprising:
a second semiconductor stack formed on the substrate and spaced apart from the first semiconductor stack, comprising a first semiconductor layer, a second semiconductor layer and an active layer formed therebetween;
a connecting electrode formed on the second semiconductor stack, electrically connecting the first semiconductor stack and the second semiconductor stack;
a second electrode formed on the second semiconductor layer of the second semiconductor stack, comprising a second pad electrode and a second finger electrode extending from the second pad electrode;
a second current blocking region formed under the second electrode, comprising a second core region under the second pad electrode and a extending region under the second finger electrode; and
a transparent conductive layer, formed on the second semiconductor layer and covering the extending region;
wherein the transparent conductive layer comprises an opening having a width wider than a width of the second pad electrode and smaller than a width of the second core region.

19. The light-emitting device of claim 11, further comprising:
a second electrode formed on the second semiconductor layer of the second semiconductor stack, comprising a second pad electrode and a second finger electrode extending from the second pad electrode;
a second current blocking region formed under the second electrode, comprising a second core region under the second pad electrode and a extending region under the second finger electrode; and
a transparent conductive layer, formed on the second semiconductor layer and covering the extending region;
wherein the transparent conductive layer comprises an opening having a width wider than a width of the second pad electrode and smaller than a width of the second core region.

20. The light-emitting device of claim 11, wherein the second finger electrode comprises a portion extending from a contour of the second pad electrode and having a width wider than other portion of the second finger electrode, and part of the portion is not covered by the transparent conductive layer.
